(19) United States
(12) Patent Application Publication
(10) Pub. No.: US 2009/0051046 A1
(43) Pub. Date: Feb. 26, 2009

(54) Semiconductor device and manufacturing method for the same

(75) Inventors: Shunpei Yamazaki, Setagaya (JP); Mikio Yukawa, Atsugi (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 12/222,555

(22) Filed: Aug. 12, 2008

(30) Foreign Application Priority Data
Aug. 24, 2007 (JP) 2007-218891
Aug. 24, 2007 (JP) 2007-219086

(51) Int. Cl. H01L 21/50; H01L 23/48

(52) U.S. Cl. 257/777; 438/109; 257/E21.499; 257/E23.01

(57) ABSTRACT

A semiconductor substrate provided with an integrated circuit is polished by CMP or the like, and the semiconductor substrate is made into a thin film by forming an embrittlement layer in the semiconductor substrate and separating a part of the semiconductor substrate; thus, semiconductor chips such as IC chips and LSI chips which are thinner than ever are obtained. Moreover, such thinned LSI chips are stacked and electrically connected through wirings penetrating through the semiconductor substrate; thus, a three dimensional semiconductor integrated circuit with improved packing density is obtained.

### BACKGROUND OF THE INVENTION

1. Field of the Invention

The present invention relates to a semiconductor device including a thinned semiconductor substrate and a method for manufacturing such a semiconductor device. The present invention particularly relates to a semiconductor device having a wiring which penetrates through a thinned semiconductor substrate and a method for manufacturing such a semiconductor device.

2. Description of the Related Art

In various scenes of social life today, information processing is performed using a computer network, and realization of a ubiquitous society where convenience of the processing of information through a computer network can be enjoyed is approaching. The term “ubiquitous” originates from Latin and means “existing everywhere”, which has been used to have the meaning of “information processing utilizing computers is naturally assimilated into our life environment without consciousness of computers”.

Actually, telephone communication or television broadcast as communication means is available using a portable electronic device categorized as a portable telephone device, and barcodes and magnetic cards which have been used for identification have been replaced with paper-like or card-like media having semiconductor chips, such as IC tags or IC cards.

By the way, in order to agreeably incorporate semiconductor chips (hereinafter, also referred to as “IC chips”, “LSI chips”, or the like) provided with integrated circuits into various things that are in the human living space, it is required to thin the semiconductor chips. For example, a product in which an IC chip is made thin to a thickness of 3 μm to 15 μm so that an IC tag having an antenna coil, a capacitor, or the like is embedded in an object to be adhered to such as paper is known (see Reference 1: Japanese Published Patent Application No. 2002-049901).

Further, due to the advance of semiconductor manufacturing technology, integration of large scale integrated circuits (LSI) has increased, and demands for system LSI in which a plurality of functions are collected on one silicon chip have been increased. In recent years, a 3D LSI in which a plurality of LSI chips are stacked is developed to be ready for higher sophistication or complication of systems. A 3D LSI is also referred to as a multi chip package (MCP) because a plurality of LSIs is provided in one package. As an example of an MCP, there is a stack MCP in which a flash memory and a static RAM are mounted in an overlapping manner.

Among stack MCPs, one in which a plurality of LSI chips are stacked and connected by wire bonding is known (for example, see References 2: Japanese Published Patent Application No. 11-204720 and Reference 3: Japanese Published Patent Application No. 2005-228930). Further, as a structure in which a plurality of silicon chips is alternately stacked and coupled to each other, and vertical interconnectors (through electrodes) are formed for stacking a plurality of LSI chips is known (for example, see Reference 4: Japanese Published Patent Application No. 11-261001).

### SUMMARY OF THE INVENTION

In order to make a semiconductor chip thin, a technique in which the rear surface of a silicon wafer provided with an integrated circuit is subjected to chemical mechanical polishing (CMP) to make the wafer into a thin layer.

Thinning of an IC chip is ideally performed to an extent where a thickness required for operation of each element of the IC chip is ensured.

Further, as to MCPs, after the rear surface of a silicon wafer provided with an LSI is subjected to CMP to make the wafer into a thin layer, such a wafer is stacked to form a multilayer. Therefore, in order that a plurality of LSI chips is stacked to fit within dimensions comparable with conventional ones, the thickness of a silicon wafer is required to be thin accordingly. Therefore, thinning of an LSI chip is ideally performed to an extent where a thickness required for operation of each element of the LSI chip is ensured.

However, since CMP is a processing technique in which a wafer is pressed against a polishing cloth while supplying an abrasive, the wafer can be processed to have a thickness of approximately 10 μm by CMP; however, it has been difficult to make a larger diameter wafer like a 12-inch wafer into a thin layer having a thickness smaller than 1 μm.

In view of the above, it is an object of the present invention to provide techniques of making semiconductor chips such as IC chips and LSI chips thinner.

Further, it is another object of the present invention to provide a technique capable of improving packing density of LSI chips by further thinning and stacking the LSI chips in three dimensional semiconductor integrated circuits typified by MCPs.

An aspect of the present invention is that a rear surface of a semiconductor substrate which is provided with an element formation layer on a surface and embedded with a first wiring electrically connected to the element formation layer is irradiated with ions, and thereby an embrittlement layer is formed; a part of the semiconductor substrate is separated along the embrittlement layer, and thereby a semiconductor substrate having the element formation layer and the first wiring is formed and a part of the first wiring is exposed at the same time; the semiconductor substrate having the element formation layer and the first wiring and a substrate provided with a second wiring are stacked; and the element formation layer and the second wiring are electrically connected.

An aspect of the present invention is a semiconductor device including a first semiconductor substrate provided with an element formation layer on a surface, a first wiring which is electrically connected to the element formation layer and penetrates through the first semiconductor substrate, and a second wiring provided for a second substrate. Further, the first wiring and the second wiring are electrically connected.

An aspect of the present invention is a semiconductor device including a first semiconductor substrate provided with an element formation layer on a surface, a first wiring which is electrically connected to the element formation layer and penetrates through the first semiconductor substrate, and a second wiring provided for a second substrate. Further, the first wiring and the second wiring are electrically connected through a conductive film formed by a plating process.

An aspect of the present invention is that an embrittlement layer is formed by performing ion irradiation on the rear surface of a semiconductor substrate of which surface is provided with an element formation layer and which is embedded with a wiring electrically connected to the element formation layer, and a part of the semiconductor substrate is separated along the embrittlement layer to form the element formation layer and a semiconductor substrate having the wiring; thus, such element formation layers and semiconductor substrates are stacked to form a multi chip.

A semiconductor substrate provided with an integrated circuit is polished by CMP or the like, and the semiconductor substrate is made into a thin film by forming an embrittlement layer in the semiconductor substrate and separating a part of the semiconductor substrate; thus, semiconductor chips such as an IC chip which is thinner than ever can be obtained.

Further, a semiconductor substrate provided with an integrated circuit such as an LSI is polished by CMP or the like, and the semiconductor substrate is made into a thin film by forming an embrittlement layer in the semiconductor substrate and separating a part of the semiconductor substrate. Thus, semiconductor chips such as an LSI chip which is thinner than ever can be obtained. Such thinned LSI chips are stacked and electrically connected through wirings penetrating through the semiconductor substrate; thus, a three dimensional semiconductor integrated circuit with improved packing density can be obtained.

### BRIEF DESCRIPTION OF THE DRAWINGS

In the accompanying drawings:

FIGS. 1A to 1C illustrate an example of a method of manufacturing a semiconductor chip of the present invention;

FIGS. 2A and 2B illustrate an example of a manufacturing method of a semiconductor chip of the present invention;

FIGS. 3A and 3B illustrate an example of an IC chip of the present invention;

FIGS. 4A and 4B illustrate an example of electrical connection with through wirings;

FIGS. 5A and 5B illustrate an example of electrical connection with through wirings;

FIG. 6 illustrates a configuration example of an IC chip package;

FIGS. 7A and 7B illustrate an example of a method for manufacturing a semiconductor device including an LSI chip of the present invention;

FIG. 8 illustrates an example of a semiconductor device including an LSI chip of the present invention;

FIG. 9 illustrates an example of a semiconductor device including an LSI chip of the present invention;

FIG. 10 illustrates an example of electrical connection with through wirings;

FIGS. 11A and 11B illustrate an example of electrical connection with through wirings;

FIGS. 12A and 12B illustrate an example of a semiconductor device including an LSI chip of the present invention;

FIG. 13 illustrates an example of a semiconductor device including an LSI chip of the present invention;

FIGS. 14A to 14C illustrate an example of a method for manufacturing a semiconductor device including an LSI chip of the present invention;

FIGS. 15A and 15B illustrate an example of a method for manufacturing a semiconductor device including an LSI chip of the present invention;

FIGS. 16A and 16B illustrate an example of a method for manufacturing a semiconductor device including an LSI chip of the present invention;

FIGS. 17A and 17B illustrate an example of a method for manufacturing a semiconductor device including an LSI chip of the present invention;

FIG. 18 illustrates an example of a method for manufacturing a semiconductor device including an LSI chip of the present invention;

FIG. 19 illustrates an example of a method for manufacturing a semiconductor device including an LSI chip of the present invention;

FIG. 20 illustrates an example of a method for manufacturing a semiconductor device including an LSI chip of the present invention;

FIGS. 21A and 21B illustrate an example of electrical connection with through wirings; and

FIGS. 22A and 22B illustrate an example of electrical connection with through wirings.

### DETAILED DESCRIPTION OF THE INVENTION

### Embodiment Modes

Embodiment Modes of the present invention will be described below with reference to the accompanying drawings. Note that the present invention is not limited to the following description, and it will be readily understood by those skilled art that various changes and modifications are possible, unless such changes and modifications depart from the spirit and the scope of the present invention. Therefore, the present invention should not be construed as being limited to the description of the embodiment modes to be given below. In the structure of the present invention which is described below, the like reference numerals may denote the like parts throughout the different drawings.

### Embodiment Mode 1

In this embodiment mode, semiconductor chips such as an IC chip or an LSI chip which have a structure obtained by, after a semiconductor substrate provided with an element formation layer and a through wiring is made into a thin film, separating a part of the semiconductor substrate, will be described with reference to the drawings. Specifically, a semiconductor chip and a method for manufacturing the semiconductor chip will be explained, the semiconductor chip having a structure obtained by, after a semiconductor substrate provided with an element formation layer and a through wiring is made into a thin film, separating a part of the semiconductor substrate, and thereby the through wiring is exposed.

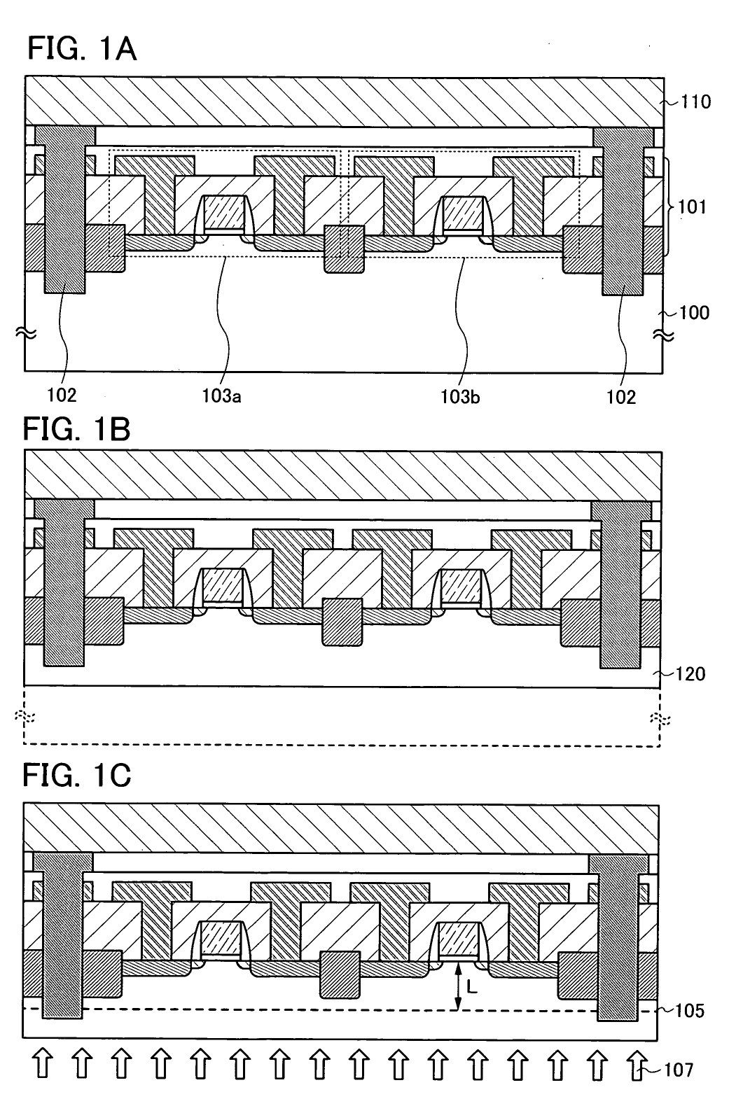

First, an element formation layer 101, a through wiring 102, and a support substrate 110 are provided over a surface of a semiconductor substrate 100 (see FIG. 1A).

As the semiconductor substrate 100, a single crystal semiconductor substrate of silicon, germanium, or the like or a polycrystalline semiconductor substrate of silicon, germanium, or the like can be used. In addition, a single crystal semiconductor substrate or a polycrystalline semiconductor substrate formed of a compound semiconductor such as gallium arsenide or indium phosphide can be used as the semiconductor substrate 100. Alternatively, as the semiconductor substrate 100, a semiconductor substrate formed of silicon having lattice distortion, silicon germanium in which germanium is added to silicon, or the like may also be used. Silicon having lattice distortion can be formed by formation of silicon on silicon germanium or silicon nitride which has larger lattice constant than silicon.

The element formation layer 101 includes elements such as a transistor, a diode, or a capacitor, which form an integrated circuit such as an LSI and wirings electrically connected to the elements. Here, an example of providing a transistor 103a and a transistor 103b on the element formation layer 101 is shown. Note that the transistor 103a and the transistor 103b which are provided on the element formation layer 101 may have a variety of structures without limitation to a certain structure.

The through wiring 102 is electrically connected to a wiring of the element formation layer 101, and a part of the through wiring 102 is embedded in the semiconductor substrate 100. The through wiring 102 is provided in a single layer or a stack which contains an element selected from aluminum (Al), tungsten (W), titanium (Ti), tantalum (Ta), molybdenum (Mo), nickel (Ni), platinum (Pt), copper (Cu), gold (Au), or silver (Ag), or an alloy material or a compound material which contains any of the above elements as its main component. Further, the through wiring 102 may serve as a through electrode in an LSI chip or an IC chip.

The support substrate 110 is provided above the element formation layer 101 (on the opposite side of the semiconductor substrate 100 with the element formation layer 101 therebetween), and a glass substrate, a quartz substrate, a plastic substrate, or the like can be used. Alternatively, the support substrate may be formed of acrylic, polyimide, an epoxy resin, or the like. Note that the support substrate 110 is not necessarily provided; however, it is preferably provided so that it serves as a protective layer when the semiconductor substrate 100 undergoes a thinning process or the like.

Next, a part of the semiconductor substrate 100 is removed to make the semiconductor substrate 100 into a thin film (see FIG. 1B). FIG. 1B illustrates a case where the semiconductor substrate 100 is made into a thin film (by removing the area surrounded by the dotted lines) to form a semiconductor substrate 120. For example, the rear surface of the semiconductor substrate 100 (on the opposite side of the surface provided with the element formation layer 101) is subjected to a grinding process, a polishing process, or a CMP process, so that the semiconductor substrate 100 can be made into a thin film.

Here, the semiconductor substrate 100 is thinned to an extent where the through wiring 102 is not exposed. Preferably, the semiconductor substrate 120 is thinned to a thickness larger than 50 nm and smaller than 1000 nm.

Next, the rear surface side of the semiconductor substrate 120 (on the opposite side of the surface provided with the element formation layer 101) is irradiated with ions 107 accelerated by an electric field as indicated by the arrow, and an embrittlement layer 105 is formed in a region of the semiconductor substrate 120 at a predetermined depth from the front surface (the surface provided with the element formation layer 101) (see FIG 1C). The embrittlement layer 105 is preferably formed using an ion doping method or an ion implantation method. Note that an ion implantation method is a technique of irradiating an object with only ions having a specific mass that are obtained by mass separation. Meanwhile, an ion doping method is a technique in which an object is irradiated with ions accelerated by an electric field without performing mass separation. The position where the embrittlement layer 105 is formed can be controlled with accelerating voltage and ion dose at the time of introduction, and the embrittlement layer 105 is formed in a region at a depth about an average penetration depth of ions. Note that in this specification, to “introduce” ions means to irradiate a semiconductor substrate with accelerated ions to have elements forming ions contained in an object. The embrittlement layer 105 is provided at a position where the through wiring 102 is exposed at the time when the semiconductor substrate 120 is separated along the embrittlement layer 105. Preferably, when the depth from the surface of the semiconductor substrate 120 is assumed to be L, the embrittlement layer 105 is provided at a position such that L is more than 50 nm and less than 1000 nm, more preferably, 100 nm to 500 nm.

As the ions 107, hydrogen ions, rare gas ions of helium or the like, or halogen ions of fluorine, chlorine, or the like can be used. The semiconductor substrate 120 is preferably irradiated with one kind of ions or plural kinds of ions of different masses each consisting of the same atom, which are produced by exciting a source gas selected from hydrogen, a rare gas, or a halogen with plasma. In the case where irradiation with hydrogen ions is performed, H⁺ ions, H₂⁺ ions, and H₃⁺ ions, and the ratio of H₃⁺ ions is made higher than that of H⁺ ions and H₂⁺; thus, ion introduction efficiency can be increased and irradiation time can be reduced.

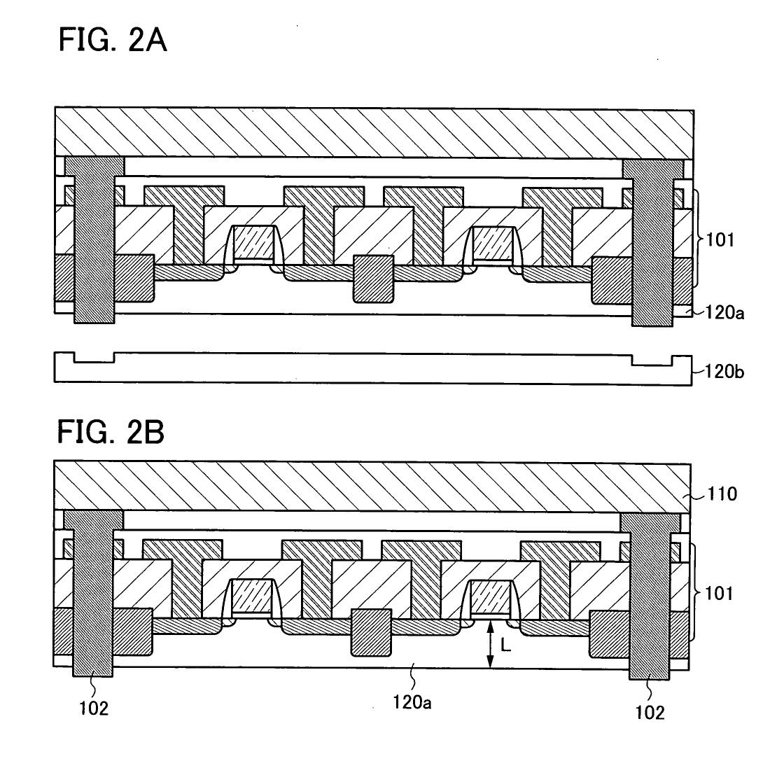

Next, the semiconductor substrate 120 is divided into the semiconductor substrate 120a and the semiconductor substrate 120b, using the embrittlement layer 105 (see FIG. 2A). Here, heat treatment is performed to divide the semiconductor substrate 120 into the semiconductor substrate 120a and the semiconductor substrate 120b along the embrittlement layer 105. For example, heat treatment is performed at a temperature ranging from 300° C. to 550° C.; thus, the volume of small voids formed in the embrittlement layer 105 changes and the semiconductor substrate 120 splits along the embrittlement layer 105, so that the thin semiconductor substrate 120a can be formed. Note that in this specification “to split” means to separate the semiconductor substrate 120b along the embrittlement layer 105 to form the semiconductor substrate 120a provided with the element formation layer 101.

Note that before the semiconductor substrate 120 is divided into the semiconductor substrate 120a and the semiconductor substrate 120b, a support substrate may be provided on the rear surface side of the semiconductor substrate 120. When the semiconductor substrate 120b to be separated is thin, a support substrate may be provided in contact with the rear surface of the semiconductor substrate 120, so that the semiconductor substrate 120 can be easily divided.

Through the above steps, a semiconductor chip such as an IC chip or an LSI chip having a structure in which the through wiring 102 penetrates the semiconductor substrate 120a provided with the element formation layer 101 and is exposed can be obtained (see FIG. 2B).

In general, when a grinding process, a polishing process, or a CMP process is used to thin a substrate, it is difficult to precisely control the thinning, so that the film thickness is liable to be irregular, and there is a limit on how thin the substrate can be made. However, as shown in this embodiment mode, after a substrate is made into a thin film, the semiconductor substrate is further divided using an embrittlement layer formed by irradiation with ions; thus, the thickness of the substrate can be small as compared to the case where only a grinding process, a polishing process, or a CMP process is performed.

### Embodiment Mode 2

In this embodiment mode, a semiconductor device having an IC chip provided with a through wiring shown in the above Embodiment Mode 1 will be described with reference to the drawings. Specifically, the case of providing an IC chip on a substrate provided with a wiring so that a through wiring of the IC chip is electrically connected to the wiring will be shown.

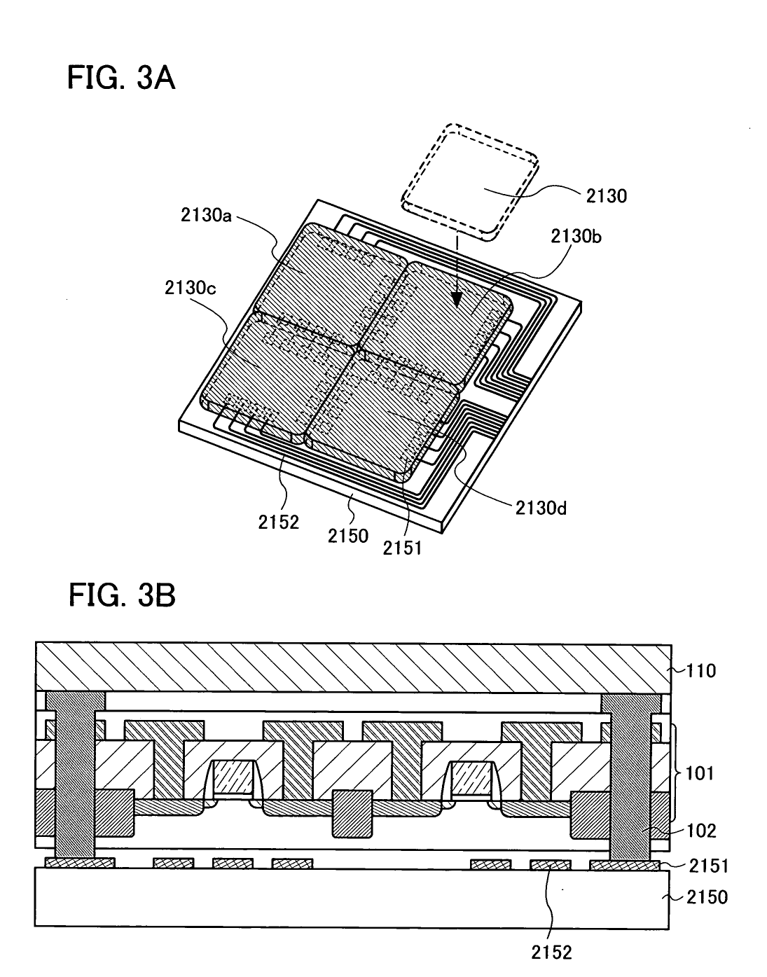

In a semiconductor device shown in FIG. 3A, an IC chip 2130 shown in the above Embodiment Mode 1 is provided by adhesion onto an interposer 2150 provided with a wiring 2152. Here, the element formation layer 101 and the wiring 2152 which are provided in a plurality of IC chips 2130a to 2130d are electrically connected to each other. The element formation layer 101 and the wiring 2152 are connected by electrically connecting the through wiring 102 provided in each of the IC chips 2130a to 2130d and a connection terminal 2151 connected to the wiring 2152 (see FIG. 3B).

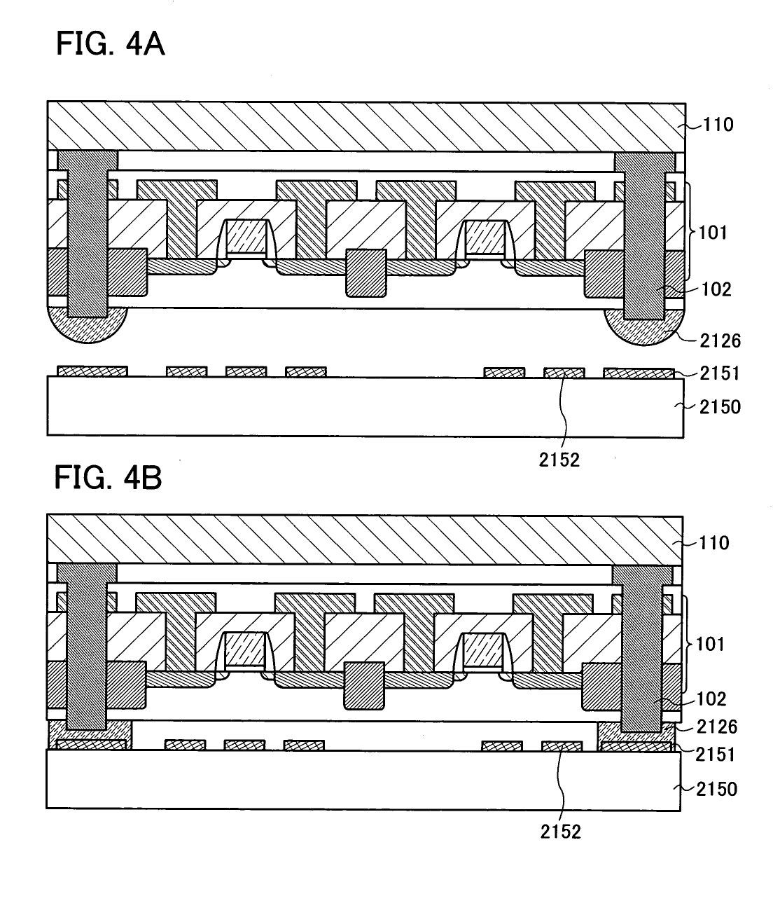

Further, an example of the case of electrically connecting the through wiring 102 and the connection terminal 2151 through a conductive material will be described with reference to FIGS. 4A and 4B.

First, a conductive material 2126 is provided on the exposed through wiring 102 (see FIG. 4A). The conductive material 2126 can be provided by selectively forming a material such as a silver paste, a copper paste, or a solder by a droplet discharge method, a screen printing method, or the like.

Next, the connection terminal 2151 is attached to the conductive material 2126 formed on the through wiring 102; thus, the through wiring 102 is electrically connected to the connection terminal 2151 (see FIG. 4B). With the provision of the conductive material 2126, connection failure between the through wiring 102 and the connection terminal 2151 can be reduced.

Note that an example of providing the conductive material 2126 on the through wiring 102 is illustrated in FIGS. 4A and 4B; however, the through wiring 102 and the connection terminal 2151 may be electrically connected to each other by, after providing the conductive material 2126 on the connection terminal 2151, attaching the through wiring 102 to the conductive material 2126.

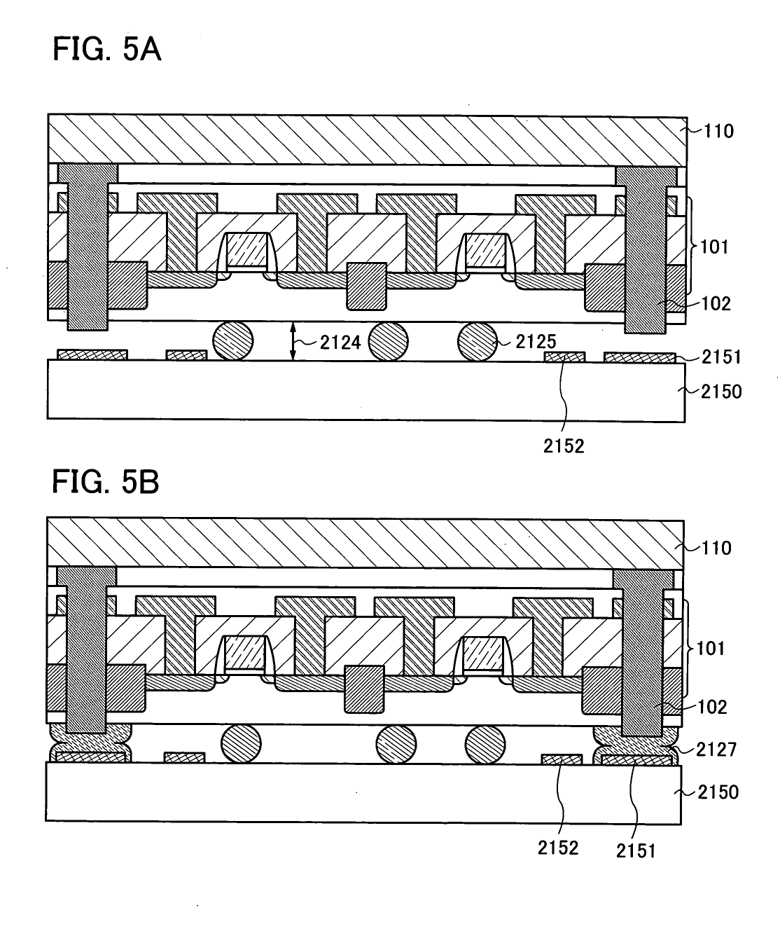

Another example of electrical connection between a through wiring and a connection terminal will be described with reference to FIGS. 5A and 5B. FIGS. 5A and 5B illustrate the case of electrically connecting the through wiring 102 and the connection terminal 2151 using a plating process.

First, an IC chip having the through wiring 102 and the interposer 2150 having the connection terminal 2151 are stacked with a space (gap) therebetween (see FIG SA). Here, spherical spacers 2125 are used to form a gap 2124 between the IC chip and the interposer 2150.

The gap 2124 is provided so that at least a plating solution can enter therein in a plating process to be performed later. Further, in order to ensure the gap 2124, the IC chip and the interposer 2150 are preferably bonded to each other with an adhesive resin such as a sealing material. Note that, here, spherical spacers are used to form the gap; however, any material can be used as long as a gap can be formed between the IC chip and the interposer 2150 without limitation to spherical spacers.

For the interposer 2150, a material such as an organic polymer or an inorganic polymer, a ceramic substrate, a glass substrate, an alumina substrate, an aluminum nitride substrate, a metal substrate, or the like can be used.

Further, FIG. 5A illustrates the case where a gap is provided also between the through wiring 102 and the connection terminal 2151 which overlap with each other; however, the through wiring 102 and the connection terminal 2151 may be provided to be in contact with each other.

Next, a conductive film is formed by deposition through a plating process between the exposed through wiring 102 and the connection terminal 2151, thereby forming a conductive film 2127. The plating process is performed until the conductive film 2127 and the connection terminal 2151 are electrically connected to each other through the through wiring 102 (see FIG. 5B). The plating process can be performed using copper (Cu), nickel (Ni), gold (Au), platinum (Pt), silver (Ag), or the like. The through wiring 102 and the connection terminal 2151 are connected using a plating process; thus, connection failure can be reduced.

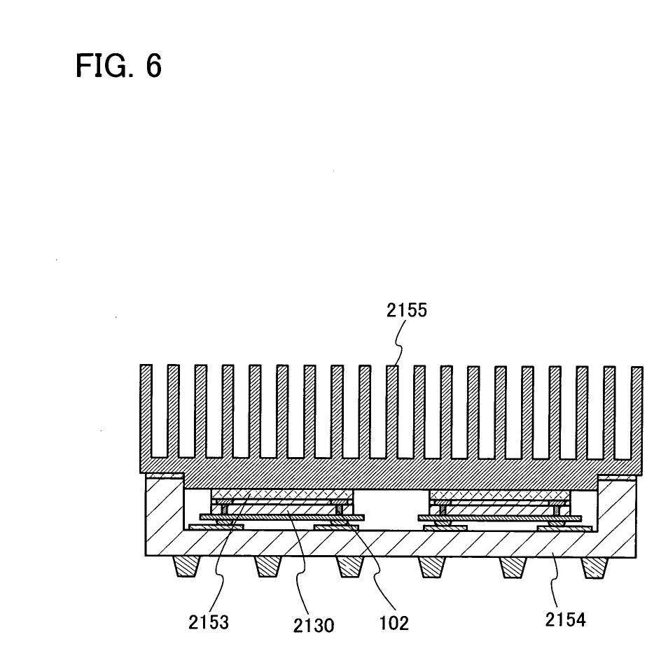

Further, a structure example of IC chip packaging will be described with reference to FIG. 6.

FIG. 6 illustrates a structure in which the IC chip 2130 is mounted on a chassis 2154 and a heat sink 2155 is provided improve heat dissipation effect. The heat sink 2155 is provided so as to cover the IC chip 2130, thereby blocking electromagnetic waves in addition to preventing heating of the IC chip 2130. Further, a part of the through wiring 102 is made to contact a heat dissipating sheet 2153, so that heat generated in the IC chip 2130 can be discharged to the heat sink 2155 through the through wiring 102. Thus, reliability of the IC chip can be increased by efficiently dissipating heat.

An IC chip can have one or more functions of a CPU, a memory, a network processing circuit, a disk processing circuit, an image processing circuit, an audio processing circuit, a power circuit, a temperature sensor, a humidity sensor, an infrared radiation sensor, and the like.

As described above, according to this embodiment mode, a semiconductor substrate provided with an integrated circuit is made into a thin film by CMP or the like and an embrittlement layer is formed in the semiconductor substrate, so that a part of the semiconductor substrate is separated to further thin the semiconductor substrate. Thus, an IC chip which is thinner than ever can be obtained.

### Embodiment Mode 3

In this embodiment mode, a semiconductor device having an LSI chip in which LSI chips shown in the above Embodiment Mode 1 are stacked will be described with reference to the drawings.

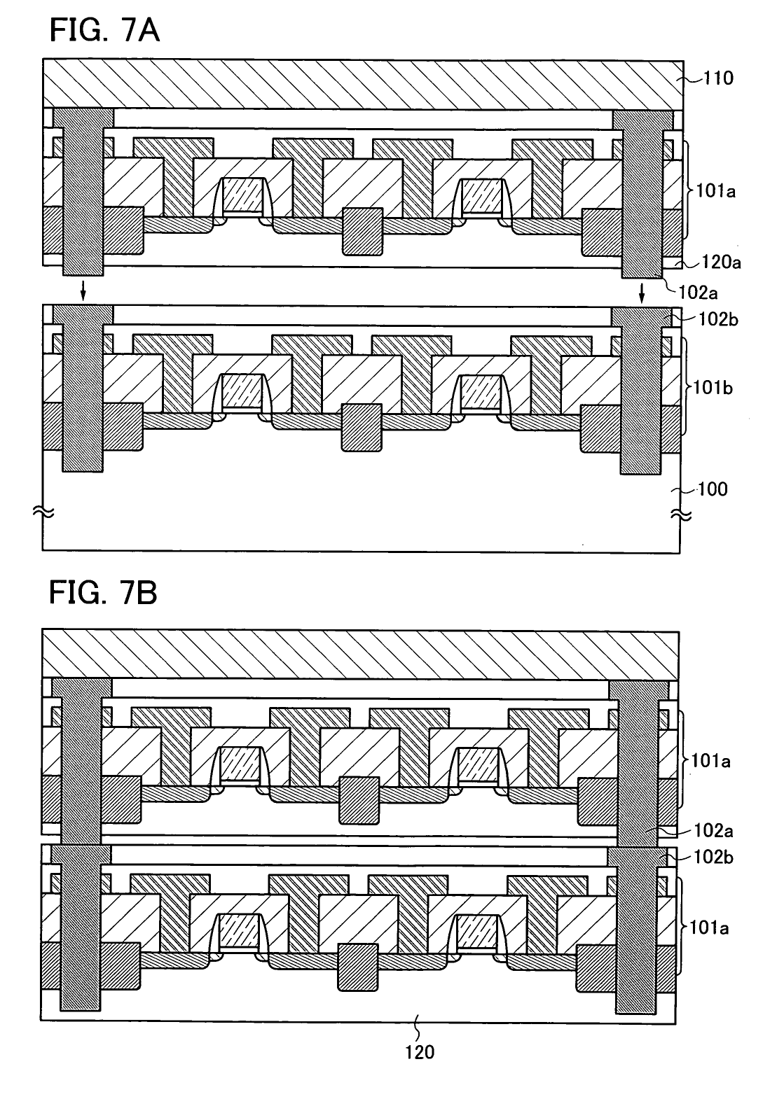

First, a first LSI chip (corresponding to the LSI chip shown in FIG. 2B) and a second LSI chip (corresponding to the LSI chip without the support substrate 110, which is shown in FIG. 1A) are prepared. The first LSI chip includes a first through wiring 102a which penetrates a semiconductor substrate 120a provided with a first element formation layer 101a and is exposed. The second LSI chip includes a second element formation layer 101b and a second through wiring 102b which are provided over a semiconductor substrate 100. Further, the first LSI chip and the second LSI chip are stacked to form a laminate so that the first through wiring 102a and the second through wiring 102b are electrically connected (see FIG. 7A).

Here, the first through wiring 102a exposed on the rear surface side of the first semiconductor substrate 120a is electrically connected to the second through wiring 102b above the second element formation layer 101b (on the opposite side of a surface which is provided with the semiconductor substrate 100); thus, a semiconductor device in which the first LSI chip and the second LSI chip are stacked can be manufactured.

The first through wiring 102a and the second through wiring 102b can be electrically connected to each other through surface activated bonding by forming a clean surface and performing heat treatment approximately at 100° C. to 400° C. Alternatively, the first through wiring 102a and the second through wiring 102b may be electrically connected to each other by forming a clean surface and performing surface activated bonding at normal temperature. The surface of the first through wiring 102a is hydrogenated with hydrogen introduced when the embrittlement layer is formed, and the surface of the second through wiring 102b may be hydrogenated by plasma treatment or the like, so that the surfaces are hardly oxidized. The first through wiring 102a and the second through wiring 102b are made to contact each other in such a state and are heated preferably at approximately 100° C. to 400° C.; thus, hydrogen is released and bonding can be formed.

As another manner, they can be electrically connected to each other by pressure bonding using an anisotropic conductive film (ACF), an anisotropic conductive paste (ACP), or the like. Alternatively, a conductive adhesive such as a silver paste, a copper paste, or a carbon paste, a solder, or the like can also be used for the connection.

Note that after the first LSI chip and the second LSI chip are stacked, the semiconductor substrate 100 is made into a thin film by a grinding process, a polishing process, or a CMP process, the laminate can be made into a thin film (see FIG. 7B). Further, when the separation process as shown in Embodiment Mode 1 is performed on the semiconductor substrate 100 in addition to a grinding process, a polishing process, or a CMP process, the laminate can be made thinner.

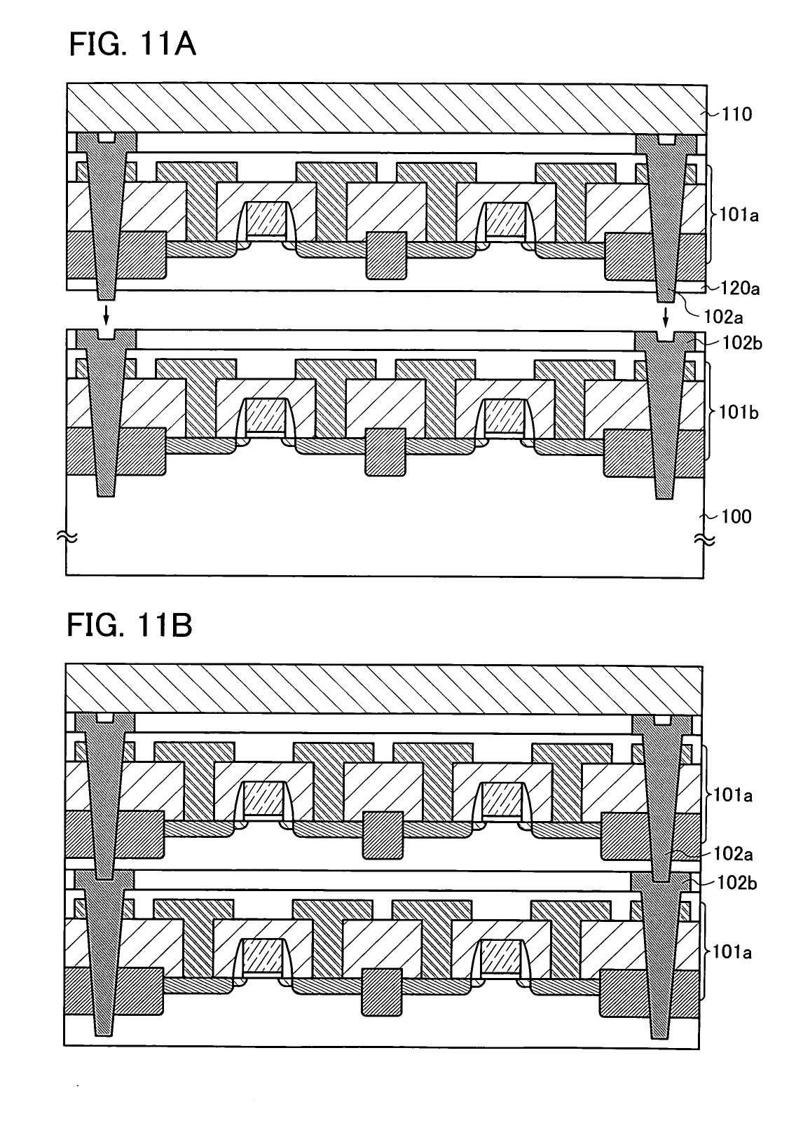

Further, in the case where electrical connection between the first through wiring 102a and the second through wiring 102b is made by a direct contact, it is preferable that the first through wiring 102a and the second through wiring 102b be engaged with each other. For example, the width of the bottom portion of the through wiring is smaller than the width of the upper portion, and a recess is provided in the top face of the through wiring; thus, the connection can be made so that the first through wiring 102a and the second through wiring 102b are engaged with each other (see FIGS. 11A and 11B).

Thus, when the connection is made so that the through wirings are engaged with each other, connection failure can be prevented. Further, the gap between the first LSI chip and the second LSI chip which are stacked can be reduced; thus, the laminate can be made into a thin film. Note that shape of the through wirings is not limited to the structure shown in FIGS. 11A and 11B. For example, a projection may be provided at the top face of a through wiring and the projection may be penetrated to the bottom face of another through wiring to make an electrical connection.

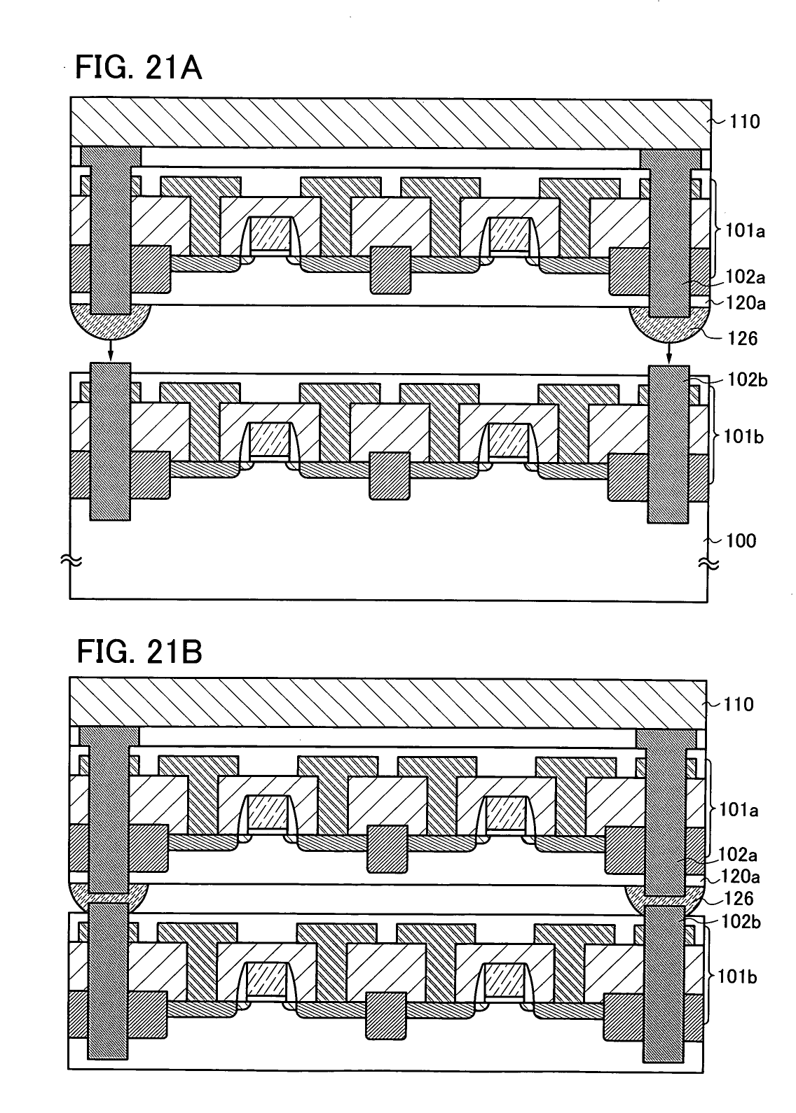

Further, an example of a case where the first through wiring 102a and the second through wiring 102b are electrically connected to each other through a conductive material will be described with reference to FIGS. 21A and 21B.

Here, first, a conductive material 126 is provided on the exposed first through wiring 102a (see FIG. 21A). The conductive material 126 may be provided by selectively forming a material such as a silver paste, a copper paste, or a carbon paste, a solder, or the like by a droplet discharge method or a screen printing method.

Next, the second through wiring 102b is attached to the conductive material 126 formed on the first through wiring 102a, and thereby the first through wiring 102a and the second through wiring 102b are electrically connected to each other (see FIG. 21B). With the provision of the conductive material 126, connection failure between the first through wiring 102a and the second through wiring 102b can be reduced.

Note that FIGS. 21A and 21B illustrate an example of the case where the conductive material 126 is provided on the first through wiring 102a; alternatively, after providing the conductive material 126 on the second through wiring 102b, the first through wiring 102a may be attached to the conductive material 126, so that the first through wiring 102a and the second through wiring 102b are electrically connected to each other.

Further, FIGS. 7A and 7B illustrate the case of manufacturing a semiconductor device having a stacked LSI chip in which two LSI chips are stacked; however, the number of the LSI chips stacked together is not limited to two.

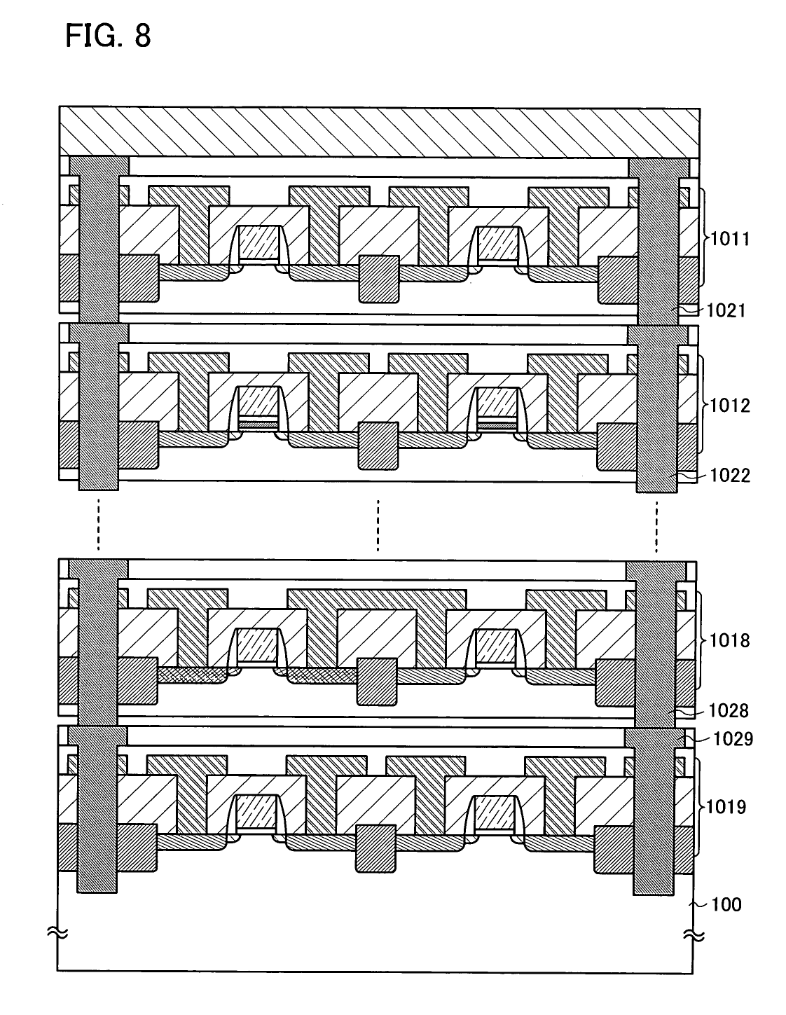

After the first LSI chip and the second LSI chip are stacked (FIG. 7A), steps shown in the above Embodiment Mode 1 are performed to expose a through wiring of the second LSI chip and a third LSI chip is stacked; thus, the three LSI chips can be stacked together. Further, when such steps are performed repeatedly, a semiconductor device having a structure in which a plurality of LSI chips is stacked can be manufactured (see FIG. 8).

FIG. 8 illustrates a semiconductor device having a stacked LSI chip having n layers (n≧2) can be manufactured. A first element formation layer 1011 provided on the first LSI chip to an n-th element formation layer 1019 provided on an n-th LSI chip are provided in a stack, and the element formation layers are electrically connected through the first through wiring 1021 to an n-th through wiring 1029.

Further, circuits having different functions can be each provided on the first element formation layer 1011 to the n-th element formation layer 1019. Here, the case where the second element formation layer 1012 is made to function as a memory circuit by providing a memory element, and an (n-1)th element formation layer 1018 is made to function as a CPU (Central Processing Unit) by providing a CMOS circuit is shown. Note that in FIG. 8, the second element formation layer 1012 is electrically connected to a second through wiring 1022, and the (n-1)th element formation layer 1018 is electrically connected to an (n-1)th through wiring 1028.

FIG. 8 illustrates the case where a through wiring is provided on each of the first LSI chip to the n-th LSI chip so that the first element formation layer to the n-th element formation layer are electrically connected; however, without limitation thereto, some of the element formation layers may be electrically connected to each other exclusively.

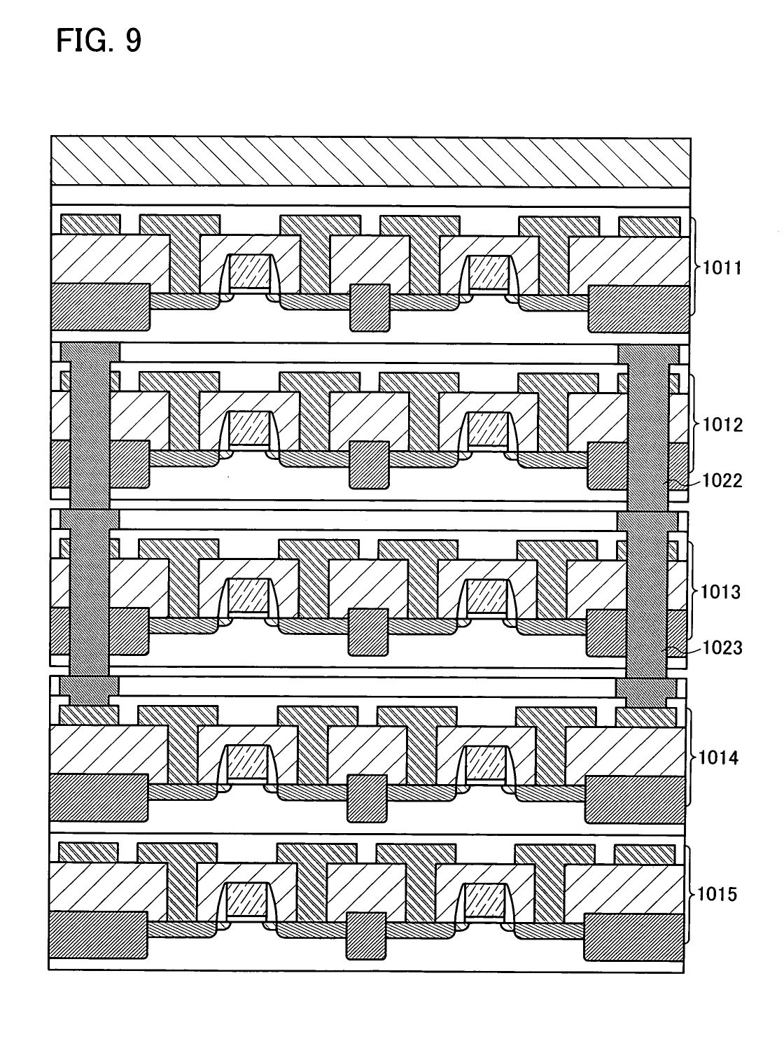

For example, FIG. 9 illustrates a semiconductor device including a stacked LSI chip having 5 layers, in which the first element formation layer 1011 provided on the first LSI chip to a fifth element formation layer 1015 provided on a fifth LSI chip are stacked. Here, the second LSI chip and the third LSI chip are provided with the second through wiring 1022 and the third through wiring 1023, respectively, so that the second element formation layer 1012 to the fourth element formation layer 1014 are electrically connected (see FIG. 9).

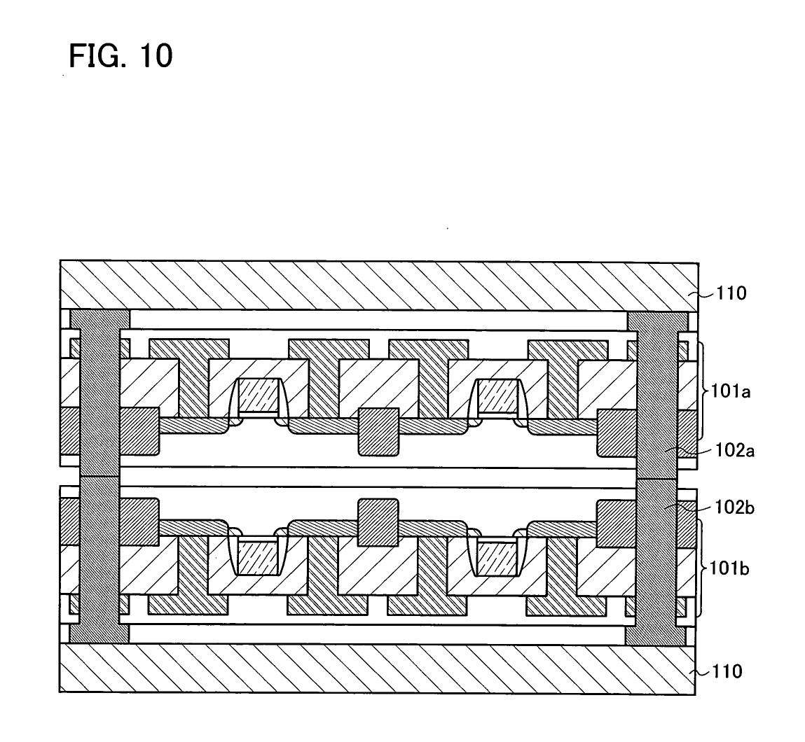

Note that in the above description, the case where the first through wiring 102a exposed on the rear surface side of the first semiconductor substrate 120a and the second through wiring 102b exposed above the second element formation layer 101b are electrically connected is shown; however, it is not limited thereto. For example, the stack may have a structure in which through wirings exposed on the rear surface side of each semiconductor substrate are electrically connected to each other (see FIG. 10). When such connections are made, even when a plurality of LSI chips is stacked, a plurality of combinations are possible; thus, design flexibility can be increased.

This embodiment mode can be implemented in combination with a structure or a manufacturing method which is shown in Embodiment Mode 1.

### Embodiment Mode 4

In this embodiment mode, a method of connecting through wirings of different LSI chips will be described with reference to the drawings. Specifically, the case of electrically connecting through wirings using a plating process will be described.

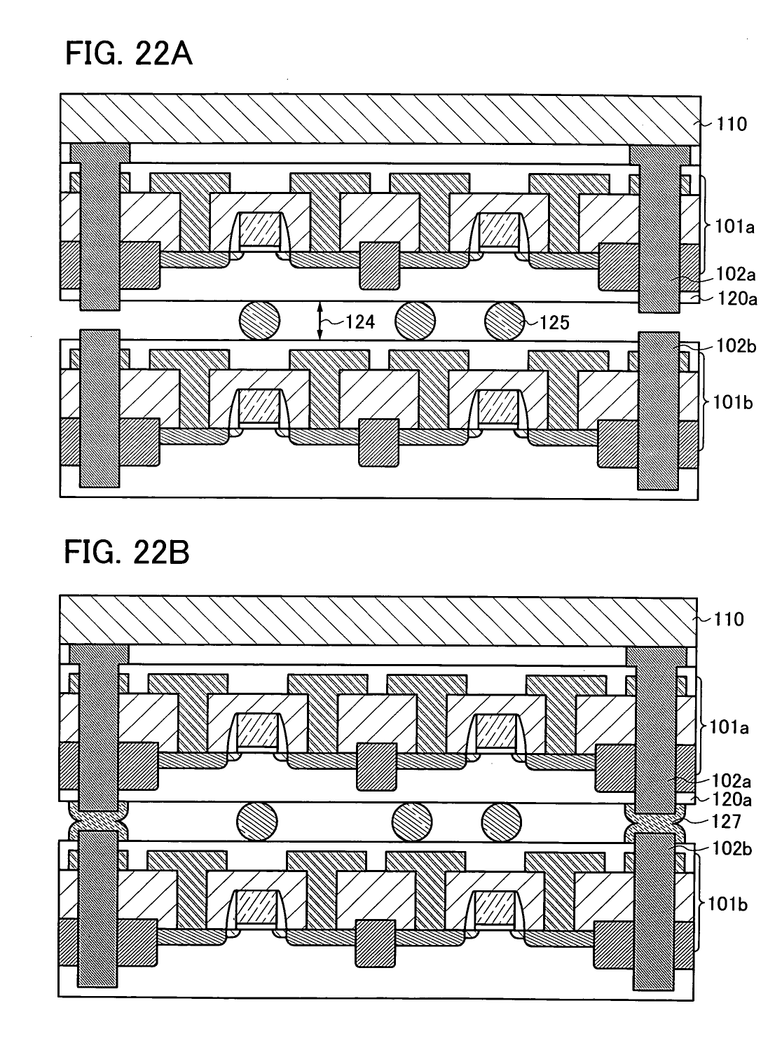

First, a first LSI chip having the first through wiring 102a and a second LSI chip having the second through wiring 102b are stacked with a space (gap) therebetween (see FIG. 22A). Here, spherical spacers 125 are used to form a gap between the first LSI chip and the second LSI chip. Further, the first LSI chip and the second LSI chip are preferably stacked so that the first through wiring 102a and the second through wiring 102b overlap with each other.

The gap 124 is provided so that at least a plating solution can enter therein in a plating process to be performed later. Further, in order to ensure the gap 124, the first LSI chip and the second LSI chip are preferably bonded to each other with an adhesive resin such as a sealing material. Note that, here, spherical spacers are used to form the gap; however, any material can be used as long as a gap can be formed between the first LSI chip and the second LSI chip without limitation to spherical spacers.

Further, FIG. 22A illustrates the case where a gap is provided also between the first through wiring 102a and the second through wiring 102b which overlap with each other; however, the first through wiring 102a and the second through wiring 102b may be provided to be in contact with each other.

Next, a conductive film is formed by deposition through a plating process between the exposed first through wiring 102a and the second through wiring 102b, thereby forming a conductive film 127. The plating process is performed until the conductive film 127 and the second through wiring 102b are electrically connected to each other through the first through wiring 102a (see FIG. 22B). The plating process can be performed using copper (Cu), nickel (Ni), gold (Au), platinum (Pt), silver (Ag), or the like.

As shown in this embodiment mode, when LSI chips are stacked together, wirings between different LSI chips are connected using a plating process; thus, connection failure can be reduced.

This embodiment mode can be implemented in combination with a structure or a manufacturing method which is shown in Embodiment Modes 1 to 3.

### Embodiment Mode 5

In this embodiment mode, a semiconductor device having an LSI chip provided with a through wiring will be described with reference to the drawings. Specifically, the case of providing a semiconductor device so that a through wiring of an LSI chip is electrically connected to a substrate provided with a wiring will be shown.

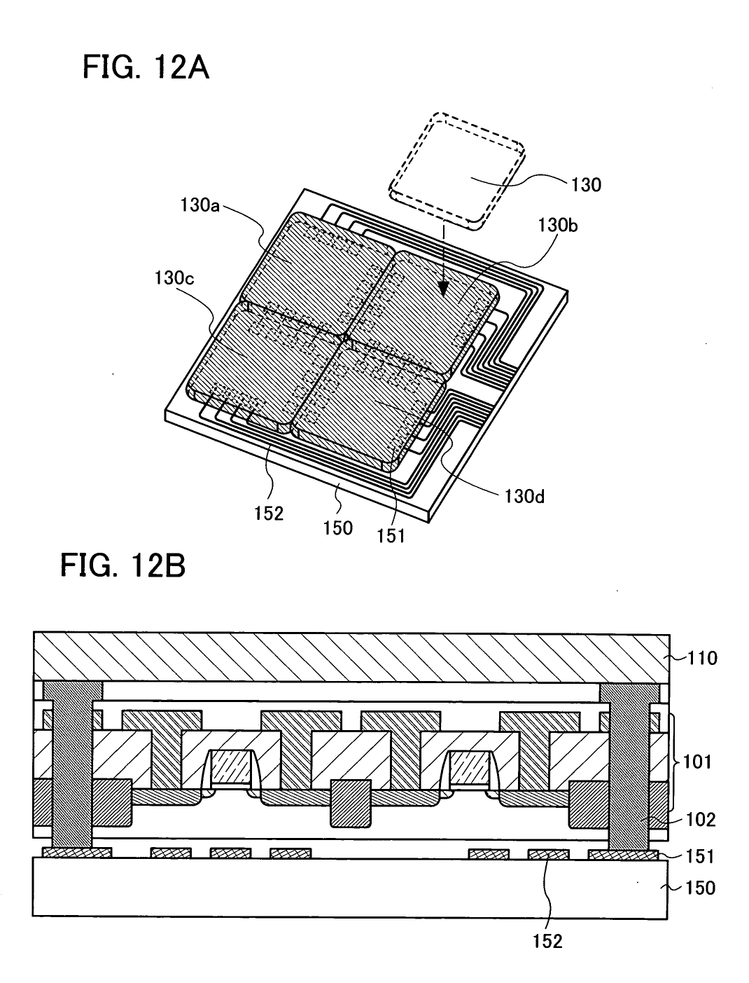

In a semiconductor device shown in FIG. 12A, an LSI chip 130 shown in the above Embodiment Mode 1 is provided by adhesion onto a substrate 150 provided with a wiring 152. Here, the element formation layer 101 and the wiring 152 which are provided in a plurality of LSI chips 130a to 130d are electrically connected to each other. The element formation layer 101 and the wiring 152 are connected by electrically connecting the through wirings 102 each provided in the LSI chips 130a to 130d and a connection terminal 151 connected to the wiring 152 (see FIG. 12B).

The through wiring 102 and the connection terminal 151 may be electrically connected by direct contact or by pressure bonding using an anisotropic conductive film, an anisotropic conductive paste, or the like. Alternatively, the connection can be made using other conductive adhesives such as a silver paste, a copper paste, or a carbon paste; a solder; or the like.

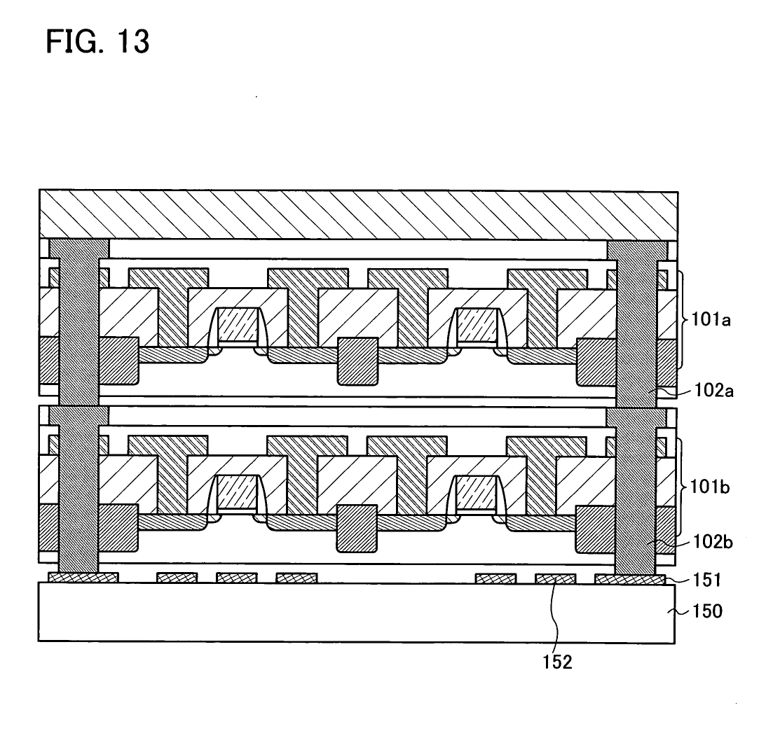

Further, in a structure shown in FIG. 12A, a stacked LSI chip shown in the above Embodiment Mode 3, in which a plurality of LSI chips are stacked may be used as the LSI chip 130 (see FIG. 13). As described above, a plurality of LSI chips are stacked to obtain a multilayer LSI chip; thus, higher integration and miniaturization of the semiconductor device can be achieved.

Each of the plurality of LSI chips can serve as one or more of a CPU, a memory, a network processing circuit, a disk processing circuit, an image processing circuit, an audio processing circuit, a power circuit, a temperature sensor, a humidity sensor, an infrared radiation sensor, and the like.

Further, when a conductive film serving as an antenna is formed over the substrate 150 and the stacked LSI chip is electrically connected to the antenna, the stacked LSI chip can be applied to a semiconductor device capable of transmitting and receiving data without contact (also referred to as an RFID (Radio Frequency Identification) tag, an ID tag, an IC tag, a wireless tag, or an electronic tag).

This embodiment mode can be implemented in combination with a structure or a manufacturing method which is shown in Embodiment Modes 1, 3, and 4.

### Embodiment Mode 6

In this embodiment mode, a structure of a semiconductor device having a stacked LSI chip, which is different from the structures shown in the above embodiment modes will be described with reference to the drawings. Specifically, the case of providing through wirings after stacking LSI chips will be described.

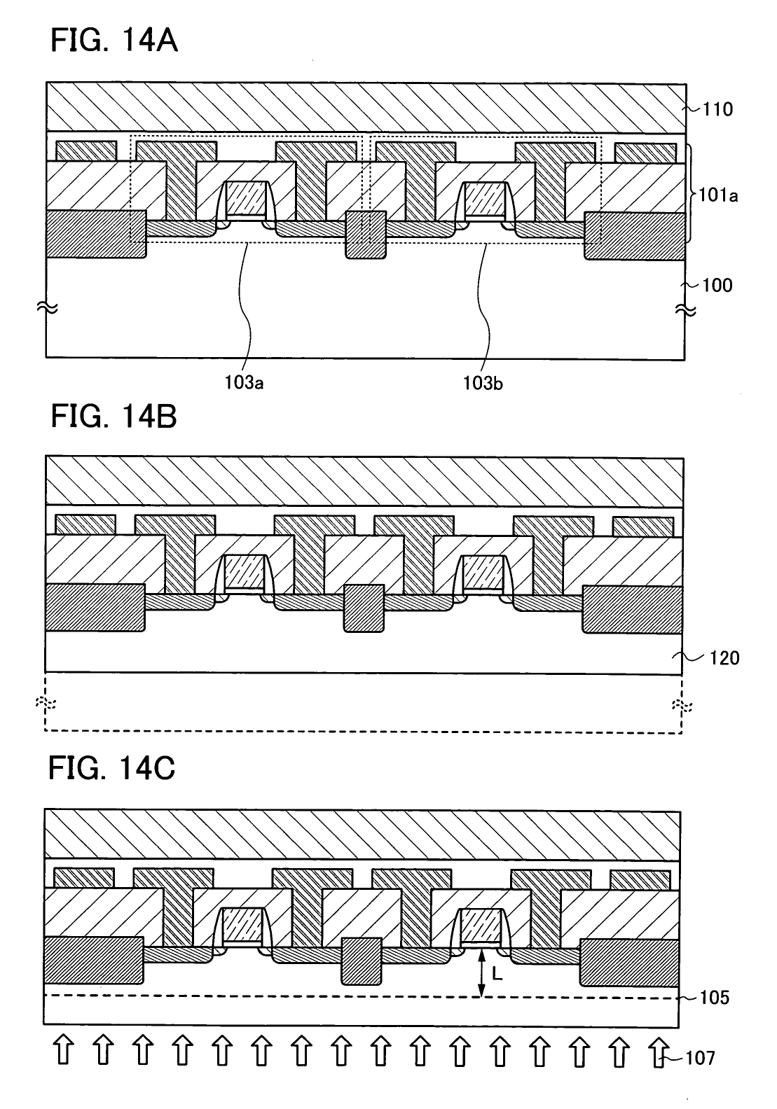

First, the first element formation layer 101a and the support substrate 110 are provided over a surface of the semiconductor substrate 100 (see FIG. 14A). Note that the through wiring 102 in the structure shown in FIG. 1A is excluded in the structure in FIG. 14A.

Note that it is not necessary to provide the support substrate 110; however, the support substrate 110 is preferably provided because it serves as a protective layer when the semiconductor substrate 100 is subjected to a thinning process, or the like.

Next, a part of the semiconductor substrate 100 is removed to make the semiconductor substrate 100 thinner (see FIG. 14B). FIG. 14B illustrates the case of thinning the semiconductor substrate 100 (by removing the area surrounded by the dotted lines) to form the semiconductor substrate 120. For example, when a grinding process, a polishing process, or a CMP process is performed on the rear surface of the semiconductor substrate 100, the semiconductor substrate 100 can be made into a thin film.

Here, the semiconductor substrate 100 is made thinner to an extent where an embedded insulating film for dividing the first element formation layer 101a and an element is not exposed. Preferably, the semiconductor substrate 120 is thinned to a thickness of 1 μm to 30 μm, preferably 5 μm to 15 μm.

Next, the rear surface side of the semiconductor substrate 120 is irradiated with ions 107 accelerated by an electric field as indicated by the arrow, and an embrittlement layer 105 is formed in a region of the semiconductor substrate 120 at a predetermined depth from the front surface (see FIG. 14C). The position where the embrittlement layer 105 is formed can be controlled with accelerating voltage and ion dose at the time of introduction. The embrittlement layer 105 is provided at a position where the separated substrate on the element formation layer 101 side is thinned to a minimum. Preferably, when the depth from the surface of the semiconductor substrate 120 is assumed to be L, the embrittlement layer 105 is provided at a position such that L is more than 10 nm and less than 1000 nm, more preferably, 100 nm to 500 nm.

In general, when a grinding process, a polishing process or a CMP process is used to thin a substrate, it is difficult to precisely control the thinning, so that the film thickness is liable to be irregular, and there is a limit on how thin the substrate can be made. However, as shown in this embodiment mode, after a substrate is made into a thin film, the semiconductor substrate is further divided using an embrittlement layer formed by irradiation with ions; thus, the thickness of the substrate can be small as compared to the case where only a grinding process, a polishing process, or a CMP process is performed.

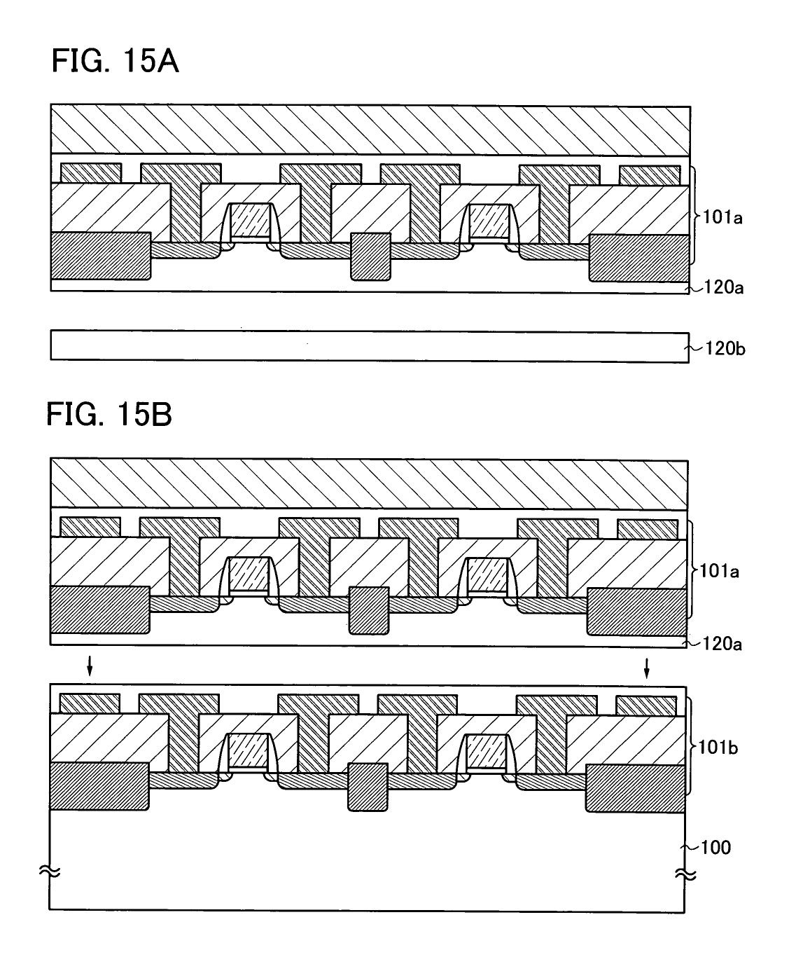

Next, the semiconductor substrate 120 is divided into the semiconductor substrate 120a and the semiconductor substrate 120b, using the embrittlement layer 105 (see FIG. 15A).

Note that before the semiconductor substrate 120 is divided into the semiconductor substrate 120a and the semiconductor substrate 120b, a support substrate may be provided on the rear surface side of the semiconductor substrate 120. When the semiconductor substrate 120b to be separated is thin, a support substrate may be provided in contact with the rear surface of the semiconductor substrate 120, so that the semiconductor substrate 120 can be easily divided.

Next, an LSI chip obtained in FIG. 15A (hereinafter referred to as “first LSI chip”) is stacked with another LSI chip provided with a second element formation layer 101b (the LSI chip without the support substrate 110 in FIG. 14A (hereinafter referred to as “second LSI chip”)) (see FIG. 15B). The first LSI chip and the second LSI chip can be attached to each other with an adhesive resin or the like.

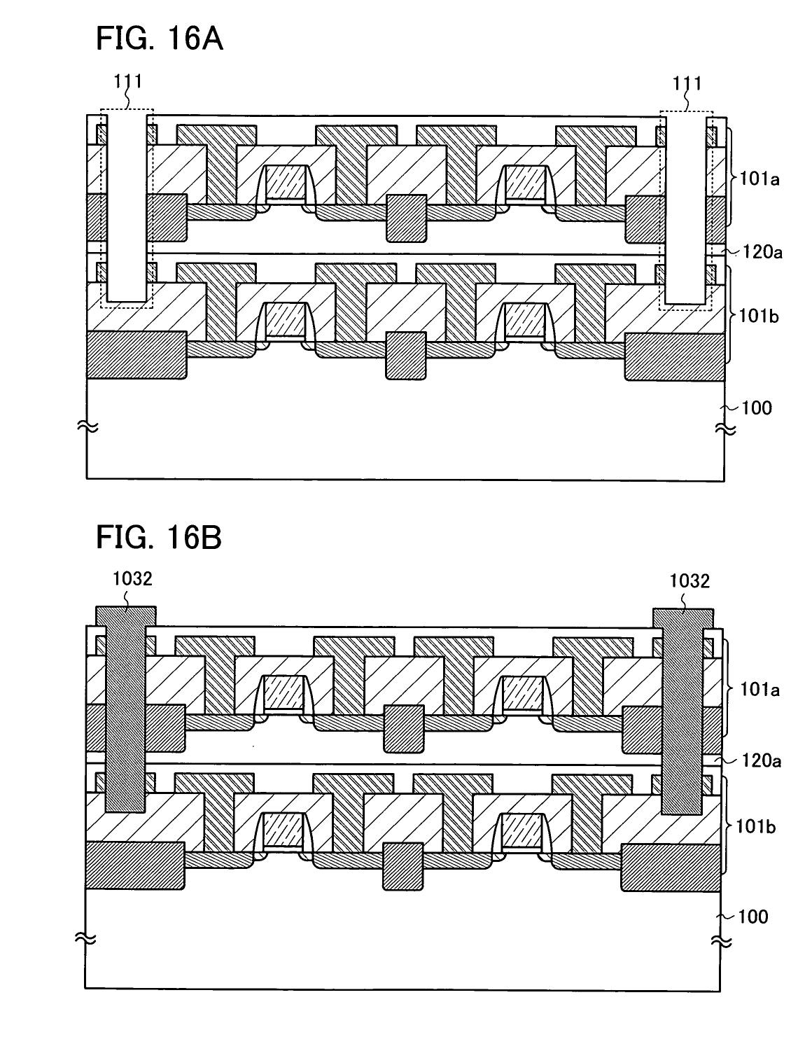

Next, after the support substrate 110 is removed, openings 111 are formed, and thereby a wiring of the first element formation layer 101a and a wiring of the second element formation layer 101b are exposed (see FIG. 16A). In this embodiment mode, since the semiconductor substrate 120a of the first LSI chip can be provided with a small thickness, the openings 111 can be formed easily.

Next, through wirings 1032 are formed in the openings 111, and thereby the first element formation layer 101a and the second element formation layer 101b are electrically connected to each other (see FIG. 16B).

The through wirings 1032 are formed using a plating process. Even when the openings 111 are deep because of the multilayer structure of the LSI chip, the through wirings 1032 can be formed to fill to the bottom of the openings 111 by a plating process. Note that the through wirings 1032 may be formed by CVD, sputtering, a screen printing method, a droplet discharge method, or the like without limitation to a plating process.

Through the above steps, a semiconductor device including a stacked LSI chip having two layers can be manufactured.

As shown in this embodiment mode, after a substrate is made into a thin film, the semiconductor substrate is further divided using an embrittlement layer formed by irradiation with ions; thus, the thickness of the semiconductor substrate can be small as compared to the case where only a grinding process, a polishing process, or a CMP process is performed. Accordingly, even in the case where a plurality of LSI chips is stacked, increase in the thickness of the laminate can be suppressed. Further, when the laminate is formed to a small film thickness, the openings can be formed easily, and the width of the through wirings can be small.

Note that when the semiconductor substrate 100 of the second LSI chip is made thinner before or after the formation of the through wirings 1032, the thickness of the laminate can be made even smaller.

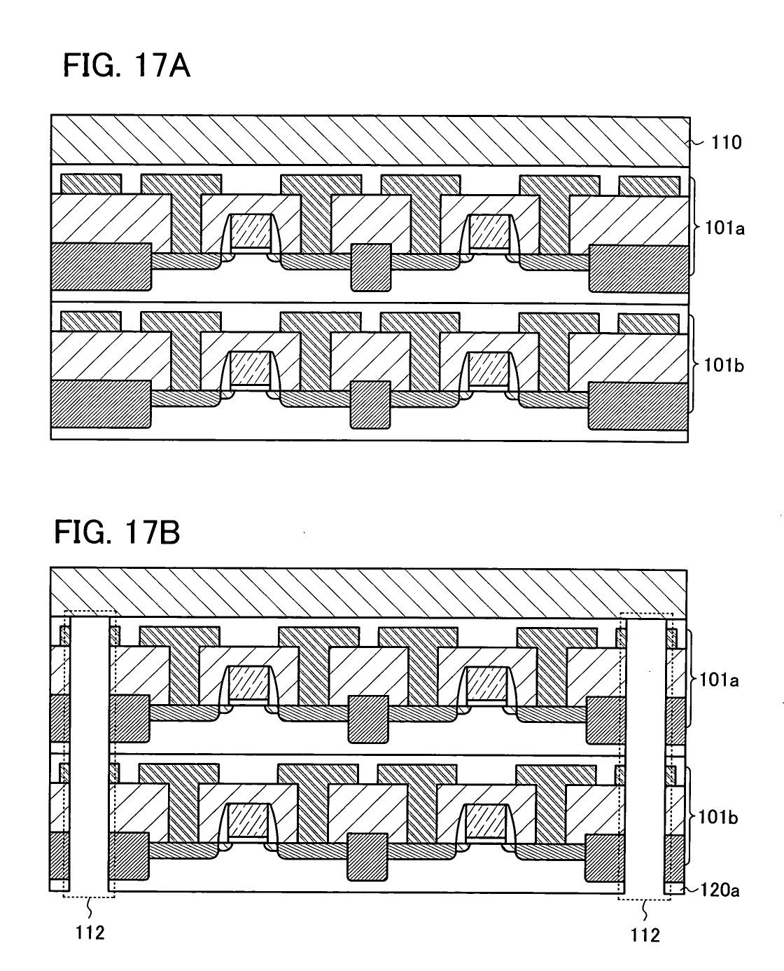

Further, in the above description, after the support substrate 110 is removed, the openings 111 are formed from the upper side of the first element formation layer 101a and the through wirings 1032 are provided; however, it is not limited thereto. For example, openings 112 may be provided from the lower side of the second element formation layer 101b and the through wirings may be provided therein. This case will be described with reference to FIGS. 17A and 17B.

First, steps up to and including the step shown in FIG. 15B are performed similarly, to stack a first LSI chip and a second LSI chip by bonding. Next, the semiconductor substrate 100 of the second LSI chip is thinned (see FIG. 17A). The thinning may be performed by a grinding process, a polishing process, or a CMP process. Further, after performing a grinding process, a polishing process, or a CMP process, separation is performed using an embrittlement layer formed by ion irradiation; thus, the semiconductor substrate of the second LSI chip can be made even thinner.

Next, the openings 112 are formed from the rear surface of the thinned semiconductor substrate 120a, and thereby a wiring of the second element formation layer 101b and a wiring of the first element formation layer 101a are exposed (see FIG. 17B). In FIG. 17A, separation is performed in addition to a grinding process, a polishing process, or a CMP process, so that the semiconductor substrate of the second LSI chip can be provided with a small thickness; thus, the openings 112 can be formed easily.

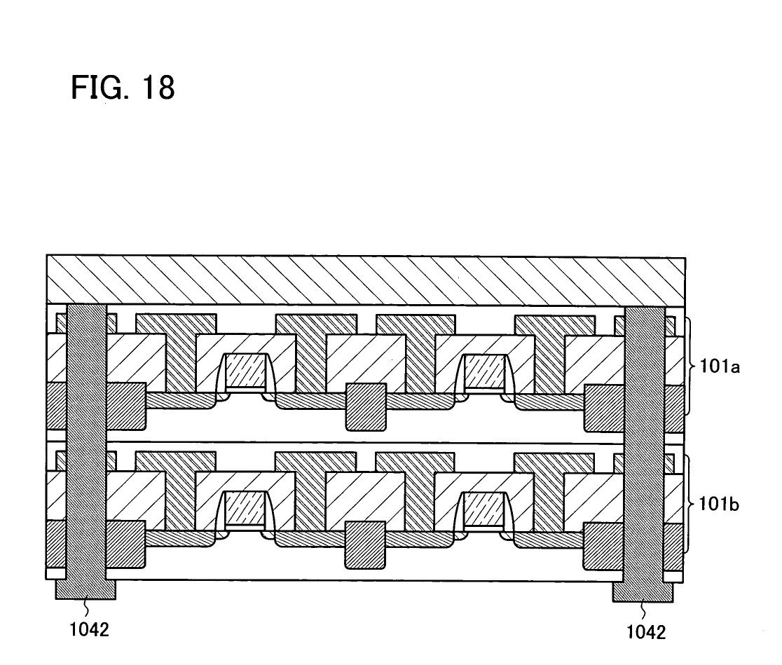

Next, through wirings 1042 are formed in the openings 112, and thereby the first element formation layer 101a and the second element formation layer 101b are electrically connected (see FIG. 18).

As above, the openings 112 may be formed from the lower side of the second element formation layer 101b thereby providing the through wirings 1042. Further, when the through wirings 1042 are provided to be exposed from the semiconductor substrate 120a of the second LSI chip, still another LSI chip or a substrate provided with a wiring may be stacked thereon.

Further, when an LSI chip is provided with a multilayer structure, after stacking an LSI chip provided with a through wiring and an LSI chip which is not provided with a through wiring, the element formation layers provided in a plurality of LSI chips may be electrically connected by providing through wirings as described above.

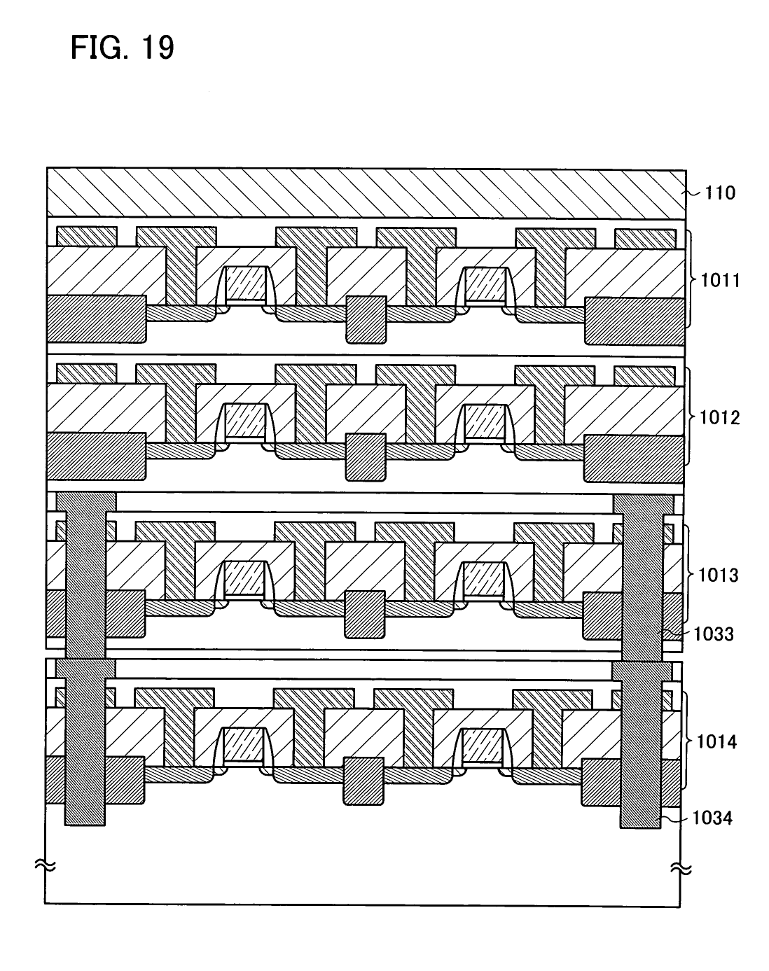

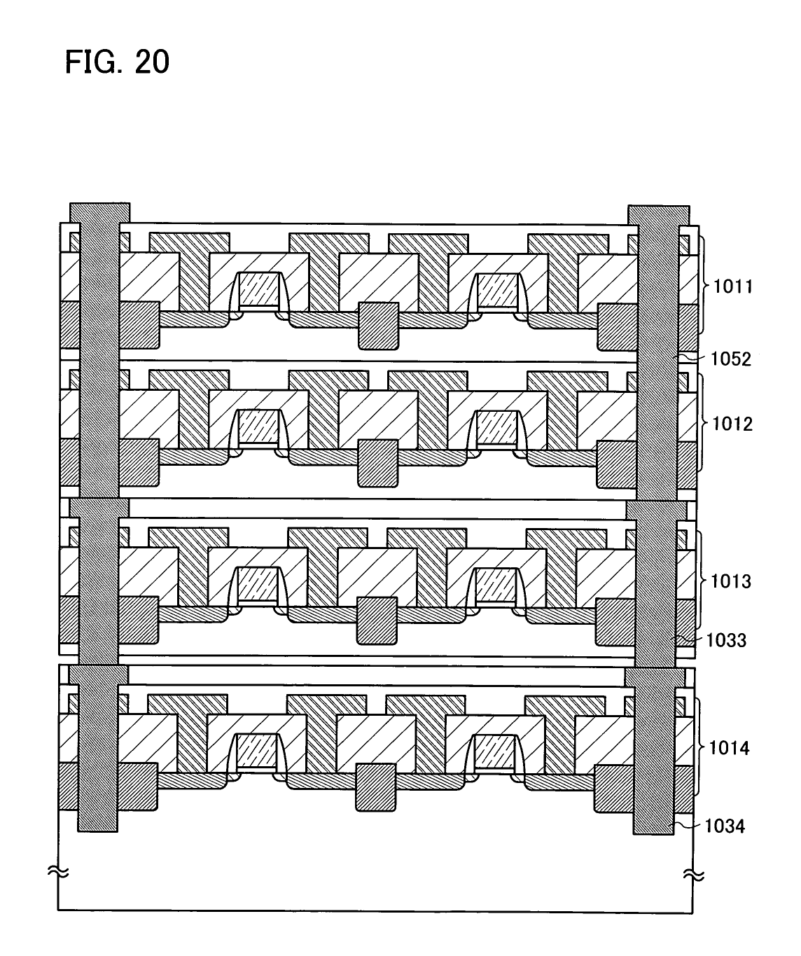

For example, a first LSI chip which is not provided with a through wiring, a second LSI chip which is not provided with a through wiring, a third LSI chip provided with a through wiring 1033, and a fourth LSI chip provided with a through wiring 1034 are sequentially stacked (see FIG. 19). Then, after forming an opening penetrating through the first element formation layer 1011 of the first LSI chip and the second element formation layer 1012 of the second LSI chip, through wirings 1052 are formed in the openings, and thereby the first element formation layer 1011 to the fourth element formation layer 1014 can be electrically connected (see FIG. 20). Note that here, four LSI chips are stacked; however, the number of LSI chips is not limited thereto.

This embodiment mode can be implemented in combination with a structure or a manufacturing method which is shown in Embodiment Mode 1 and Embodiment Modes 3 to 5.

This application is based on Japanese Patent Application serial no. 2007-218891 and Japanese Patent Application serial no. 2007-219086 which are filed with Japan Patent Office on Aug. 24, 2007, and the entire contents of which are hereby incorporated by reference.

What is claimed is:

1. A method for manufacturing a semiconductor device comprising:
irradiating with ions, a rear surface of a first semiconductor substrate which is provided with an element formation layer on a surface and embedded with a first wiring electrically connected to the element formation layer to form an embrittlement layer in a region at a predetermined depth from a surface of the first semiconductor substrate;
separating a part of the first semiconductor substrate along the embrittlement layer to form a first semiconductor substrate having the element formation layer and the first wiring and expose a part of the first wiring at the same time;
stacking the first semiconductor substrate having the element formation layer and the first wiring and a second substrate provided with a second wiring, with the first wiring and the second wiring therebetween; and
electrically connecting the element formation layer and the second wiring with an adhesive conductive material for bonding a part of the first wiring and the second wiring.

2. A method for manufacturing a semiconductor device comprising:
irradiating with ions, a rear surface of a first semiconductor substrate which is provided with a first element formation layer on a surface and embedded with a first wiring electrically connected to the first element formation layer to form an embrittlement layer in a region at a predetermined depth from a surface of the first semiconductor substrate;
separating a part of the first semiconductor substrate along the embrittlement layer to form a first semiconductor substrate having the first element formation layer and the first wiring and expose a part of the first wiring at the same time;
stacking the first semiconductor substrate having the first element formation layer and the first wiring and a second semiconductor substrate provided with a second element formation layer and a second wiring electrically connected to the second element formation layer, with the first wiring and the second wiring therebetween; and
electrically connecting the first element formation layer and the second element formation layer with an adhesive conductive material for bonding a part of the first wiring and the second wiring.

3. A method for manufacturing a semiconductor device according to claim 1,
wherein the conductive material is formed using a silver paste, a copper paste, or a solder.

4. A method for manufacturing a semiconductor device according to claim 2,
wherein the conductive material is formed using a silver paste, a copper paste, or a solder.

5. A method for manufacturing a semiconductor device comprising:
irradiating with ions, a rear surface of a first semiconductor substrate which is provided with an element formation layer on a surface and embedded with a first wiring electrically connected to the element formation layer to form an embrittlement layer in a region at a predetermined depth from a surface of the first semiconductor substrate;
separating a part of the first semiconductor substrate along the embrittlement layer to form a first semiconductor substrate having the element formation layer and the first wiring and expose a part of the first wiring at the same time;
stacking the first semiconductor substrate having the element formation layer and the first wiring and a second substrate having a second wiring, with the first wiring and the second wiring therebetween; and
forming a conductive film between a part of the first wiring and the second wiring by a plating process to electrically connect the element formation layer and the second wiring.

6. A method for manufacturing a semiconductor device comprising:
forming an embrittlement layer in a region at a predetermined depth from a surface of a first semiconductor substrate by irradiating with ions, a rear surface of the first semiconductor substrate which is provided with a first element formation layer on a surface and embedded with a first wiring electrically connected to the first element formation layer;
separating a part of the first semiconductor substrate along the embrittlement layer to form a first semiconductor substrate having the first element formation layer and the first wiring and expose a part of the first wiring at the same time;
stacking the first semiconductor substrate having the first element formation layer and the first wiring and a second semiconductor substrate provided with a second element formation layer and a second wiring electrically connected to the second element formation layer, with the first wiring and the second wiring therebetween; and
forming a conductive film between a part of the first wiring and the second wiring by a plating process to electrically connect the first element formation layer and the second element formation layer.

7. A method for manufacturing a semiconductor device according to claim 5,
wherein the plating process is performed using copper, nickel, gold, or platinum.

8. A method for manufacturing a semiconductor device according to claim 6,
wherein the plating process is performed using copper, nickel, gold, or platinum.

9. A method for manufacturing a semiconductor device comprising:
irradiating with ions, a rear surface of a first semiconductor substrate which is provided with a first element formation layer on a surface and embedded with a first wiring electrically connected to the first element formation layer to form a first embrittlement layer in a region at a predetermined depth from a surface of the first semiconductor substrate;
separating a part of the first semiconductor substrate along the first embrittlement layer to form a first semiconductor substrate having the first element formation layer and the first wiring and expose a part of the first wiring at the same time;
stacking the first semiconductor substrate having the first element formation layer and the first wiring and a second semiconductor substrate having a second element formation layer provided on a surface and a second wiring electrically connected to the second element layer, with the second element formation layer therebetween;
electrically connecting a part of the first wiring and the second wiring to electrically connect the first element formation layer and the second element formation layer;
irradiating a rear surface of the second semiconductor substrate with ions to form a second embrittlement layer in a region at a predetermined depth from the surface of the second semiconductor substrate; and
separating a part of the second semiconductor substrate along the second embrittlement layer.

10. A method for manufacturing a semiconductor device according to claim 9,
wherein the part of the first wiring is engaged in a recess provided in the second wiring to electrically connect the part of the first wiring and the second wiring.

11. A method for manufacturing a semiconductor device according to claim 9,
wherein a projection provided on the second wiring is penetrated to the part of the first wiring to electrically connect the part of the first wiring and the second wiring.

12. A method for manufacturing a semiconductor device according to claim 9,
wherein the part of the first wiring and the second wiring are electrically connected to each other by performing heat treatment of 100° C. to 400° C.

13. A method for manufacturing a semiconductor device comprising:
irradiating with ions, a rear surface of a first semiconductor substrate which is provided with a first element formation layer on a surface and embedded with a first wiring electrically connected to the first element formation layer to form a first embrittlement layer in a region at a predetermined depth from a surface of the first semiconductor substrate;
separating a part of the first semiconductor substrate along the first embrittlement layer to form a first semiconductor substrate having the first element formation layer and the first wiring and expose a part of the first wiring at the same time;
irradiating with ions, a rear surface of a second semiconductor substrate having a second element formation layer provided on a surface and a second wiring electrically connected to the second element formation layer to form a second embrittlement layer in a region at a predetermined depth from a surface of the second semiconductor substrate;
separating a part of the second semiconductor substrate along the second embrittlement layer to form a second semiconductor substrate having the second element formation layer and the second wiring and exposing a part of the second wiring at the same time;
stacking the first semiconductor substrate and the second semiconductor substrate with a part of the first wiring and a part of the second wiring therebetween; and
electrically connecting the part of the first wiring and the part of the second wiring.

14. A method for manufacturing a semiconductor device according to claim 13,
wherein the part of the first wiring and the part of the second wiring are electrically connected to each other by performing heat treatment of 100° C. to 400° C.

15. A method for manufacturing a semiconductor device comprising:
irradiating with ions, a rear surface of a first semiconductor substrate provided with a first element formation layer to form an embrittlement layer in a region at a predetermined depth from a surface of the first semiconductor substrate;
separating a part of the first semiconductor substrate along the embrittlement layer to form a first semiconductor substrate provided with the first element formation layer;
stacking the first semiconductor substrate provided with the first element formation layer and a second semiconductor substrate provided with a second element formation layer with the second element formation layer therebetween;
forming an opening in the first element formation layer, the first semiconductor substrate, and the second semiconductor substrate; and
forming a wiring in the opening to electrically connect the first element formation layer and the second element formation layer.

16. A method for manufacturing a semiconductor device comprising:
irradiating with ions, a rear surface of a first semiconductor substrate provided with a first element formation layer on a surface to form a first embitterment layer in a region at a predetermined depth from the surface of the first semiconductor substrate;
separating a part of the first semiconductor substrate along the first embrittlement layer to form a first semiconductor substrate provided with the first element formation layer;
irradiating with ions, a rear surface of a second semiconductor substrate provided with a second element formation layer on a surface to form a second embitterment layer in a region at a predetermined depth from the surface of the second semiconductor substrate;
separating a part of the second semiconductor substrate along the second embrittlement layer to form a second semiconductor substrate provided with the second element formation layer;
stacking the first semiconductor substrate provided with the first element formation layer and a second semiconductor substrate provided with a second element formation layer, with the second element formation layer therebetween;
forming an opening in the first semiconductor substrate provided with the first element formation layer, the second element formation layer, and the second semiconductor substrate provided with the second element formation layer; and
forming a wiring in the opening to electrically connect the first element formation layer and the second element formation layer.

17. A method for manufacturing a semiconductor device according to claim 1,
wherein the ions are hydrogen ions, halogen ions, or rare gas ions.

18. A method for manufacturing a semiconductor device according to claim 2,
wherein the ions are hydrogen ions, halogen ions, or rare gas ions.

19. A method for manufacturing a semiconductor device according to claim 5,
wherein the ions are hydrogen ions, halogen ions, or rare gas ions.

20. A method for manufacturing a semiconductor device according to claim 6,
wherein the ions are hydrogen ions, halogen ions, or rare gas ions.

21. A method for manufacturing a semiconductor device according to claim 9,
wherein the ions are hydrogen ions, halogen ions, or rare gas ions.

22. A method for manufacturing a semiconductor device according to claim 13,
wherein the ions are hydrogen ions, halogen ions, or rare gas ions.

23. A method for manufacturing a semiconductor device according to claim 15,
wherein the ions are hydrogen ions, halogen ions, or rare gas ions.

24. A method for manufacturing a semiconductor device according to claim 16,
wherein the ions are hydrogen ions, halogen ions, or rare gas ions.

25. A method for manufacturing a semiconductor device according to claim 1,
wherein the ions include H⁺ ions, H₂⁺ ions, and H₃⁺ rare gas ions, and
a ratio of the H₃⁺ ions is higher than a ratio of the H₂⁺ ions.

26. A method for manufacturing a semiconductor device according to claim 2,
wherein the ions include H⁺ ions, H₂⁺ ions, and H₃⁺ rare gas ions, and
a ratio of the H₃⁺ ions is higher than a ratio of the H₂⁺ ions.

27. A method for manufacturing a semiconductor device according to claim 5,
wherein the ions include H⁺ ions, H₂⁺ ions, and H₃⁺ rare gas ions, and
a ratio of the H₃⁺ ions is higher than a ratio of the H₂⁺ ions.

28. A method for manufacturing a semiconductor device according to claim 6,
wherein the ions include H⁺ ions, H₂⁺ ions, and H₃⁺ rare gas ions, and
a ratio of the H₃⁺ ions is higher than a ratio of the H₂⁺ ions.

29. A method for manufacturing a semiconductor device according to claim 9,
wherein the ions include H⁺ ions, H₂⁺ ions, and H₃⁺ rare gas ions, and
a ratio of the H₃⁺ ions is higher than a ratio of the H₂⁺ ions.

30. A method for manufacturing a semiconductor device according to claim 13,
wherein the ions include H⁺ ions, H₂⁺ ions, and H₃⁺ rare gas ions, and
a ratio of the H₃⁺ ions is higher than a ratio of the H₂⁺ ions.

31. A method for manufacturing a semiconductor device according to claim 15,
wherein the ions include H⁺ ions, H₂⁺ ions, and H₃⁺ rare gas ions, and
a ratio of the H₃⁺ ions is higher than a ratio of the H₂⁺ ions.

32. A method for manufacturing a semiconductor device according to claim 16,
wherein the ions include H⁺ ions, H₂⁺ ions, and H₃⁺ rare gas ions, and
a ratio of the H₃⁺ ions is higher than a ratio of the H₂⁺ ions.

33. A method for manufacturing a semiconductor device according to claim 1,
wherein a grinding process, a polishing process, or a CMP process is performed on the rear surface of the first semiconductor substrate before irradiating the first semiconductor substrate with ions.

34. A method for manufacturing a semiconductor device according to claim 2,
wherein a grinding process, a polishing process, or a CMP process is performed on the rear surface of the first semiconductor substrate before irradiating the first semiconductor substrate with ions.

35. A method for manufacturing a semiconductor device according to claim 5,
wherein a grinding process, a polishing process, or a CMP process is performed on the rear surface of the first semiconductor substrate before irradiating the first semiconductor substrate with ions,.

36. A method for manufacturing a semiconductor device according to claim 6,
wherein a grinding process, a polishing process, or a CMP process is performed on the rear surface of the first semiconductor substrate before irradiating the first semiconductor substrate with ions.

37. A method for manufacturing a semiconductor device according to claim 9,
wherein a grinding process, a polishing process, or a CMP process is performed on the rear surface of the first semiconductor substrate before irradiating the first semiconductor substrate with ions.

38. A method for manufacturing a semiconductor device according to claim 13,
wherein a grinding process, a polishing process, or a CMP process is performed on the rear surface of the first semiconductor substrate before irradiating the first semiconductor substrate with ions.

39. A method for manufacturing a semiconductor device according to claim 15,
wherein a grinding process, a polishing process, or a CMP process is performed on the rear surface of the first semiconductor substrate before irradiating the first semiconductor substrate with ions.

40. A method for manufacturing a semiconductor device according to claim 16,
wherein a grinding process, a polishing process, or a CMP process is performed on the rear surface of the first semiconductor substrate before irradiating the first semiconductor substrate with ions.

41. A semiconductor device comprising:
a first semiconductor substrate provided with an element formation layer on a surface;
a first wiring which is electrically connected to the element formation layer and penetrates through the first semiconductor substrate;
a second wiring provided for a second substrate; and
a conductive material for bonding the first wiring and the second wiring.

42. A semiconductor device comprising:
a first semiconductor substrate provided with a first element formation layer on a surface;
a first wiring which is electrically connected to the first element formation layer and penetrates through the first semiconductor substrate;
a second semiconductor substrate provided with a second element formation layer on a surface;
a second wiring penetrating through the second element formation layer; and
a conductive material for bonding the first wiring and the second wiring.

43. A semiconductor device according to claim 41,
wherein the conductive material is provided using a silver paste, a copper paste, or a solder.

44. A semiconductor device according to claim 42,
wherein the conductive material is provided using a silver paste, a copper paste, or a solder.

45. A semiconductor device comprising:
a first semiconductor substrate provided with an element formation layer on a surface;
a first wiring which is electrically connected to the element formation layer and penetrates through the first semiconductor substrate;
a second wiring provided for a second substrate; and
a conductive film provided between the first wiring and the second wiring by a plating process.

46. A semiconductor device comprising:
a first semiconductor substrate provided with a first element formation layer on a surface;
a first wiring which is electrically connected to the first element formation layer and penetrates through the first semiconductor substrate;
a second semiconductor substrate provided with a second element formation layer on a surface;
a second wiring penetrating through the second element formation layer; and
a conductive film provided between the first wiring and the second wiring by a plating process.

47. A semiconductor device according to claim 45,
wherein the plating process is performed using copper, nickel, gold, or platinum.

48. A semiconductor device according to claim 46,
wherein the plating process is performed using copper, nickel, gold, or platinum.

49. A semiconductor device according to claim 41,
wherein a thickness of the first semiconductor substrate is 100 nm to 500 nm.

50. A semiconductor device according to claim 42,
wherein a thickness of the first semiconductor substrate is 100 nm to 500 nm.

51. A semiconductor device according to claim 45,
wherein a thickness of the first semiconductor substrate is 100 nm to 500 nm.

52. A semiconductor device according to claim 46,
wherein a thickness of the first semiconductor substrate is 100 nm to 500 nm.
